(19) United States
(12) Patent Application Publication
(10) Pub. No.: US 2014/0326778 A1
(43) Pub. Date: Nov. 6, 2014

(54) ULTRASONIC WIRE BONDING WEDGE WITH MULTIPLE BONDING WIRE SLOTS

(71) Applicant: Shang-Che Lee, Hsinchu County (TW)

(72) Inventor: Shang-Che Lee, Hsinchu County (TW)

(21) Appl. No.: 13/888,189

(22) Filed: May 6, 2013

(51) Int. Cl. H01L 23/00; B23K 20/10

(52) U.S. Cl. CPC H01L 24/78; B23K 20/106
USPC 228/1.1

(57) ABSTRACT

An ultrasonic wire bonding wedge with multiple bonding wire slots is provided. The wire bonding wedge includes a pillar fixing part for providing fixed connection to the bonding device. One end of the fixing part includes a wire bonding wedge nozzle, with feature that the tip of the nozzle including at least two bonding wire slots. The tip of nozzle of the wire bonding wedge includes at least two bonding wire slots, and is able to realize bonding operations between two or more bonding wires and the chips to improve bonding operation efficiency. When bonding operation is performed on a smaller bonding area, or two or more parallel bonding wires, the wire bonding wedge is able to perform a single bonding operation in a smaller bonding operation so as to reduce defective rate of the chips and ensure sufficient bonding strength of the bonding operation.

### FIELD OF THE INVENTION

The present invention generally relates to semiconductor packaging technique, and more specifically to an ultrasonic wire bonding wedge with multiple bonding wire slots.

### BACKGROUND OF THE INVENTION

In the semiconductor packaging process, metal bonding wires are used for bonding and wiring to form electrical pathway between electrodes and lead frame on the semiconductor elements. The conventional wiring of IC or semiconductor elements, as shown in FIG. 1, is: using wire bonding wedge 91 to press a bonding wire 92 on the bonding area of a chip 93; propagating high frequency oscillation from ultrasonic bonding equipment through wire bonding wedge 91 to between the surface of bonding wire 92 and the bonding area of chip 93 so that the mechanic friction between the metal surfaces to be welded under pressure making fusion of the contact molecular layers of bonding wire 92 and the chip 93 to achieve bonding.

The conventional wire bonding wedge 91 used in the above technique includes only a bonding wire slot 94 at the tip. Therefore, only a bonding wire can be fixed by each movement. In actual operation, a plurality of bonding wires is often used. Hence, the above ultrasonic bonding operation is of low efficiency. In addition, when applied to a smaller bonding area, to weld two or more parallel bonding wires, the conventional wire bonding wedge 91 cannot meet the design requirement even with multiple runs of operations, and a slight error may render the chip useless. Thus, it is imperative to devise an alternative to the conventional wire bonding wedge 91 to address the above drawbacks.

### SUMMARY OF THE INVENTION

The present invention has been made to overcome the above-mentioned drawback of conventional technique. The primary object of the present invention is to provide an ultrasonic wire bonding wedge. The ultrasonic wire bonding wedge is able to realize simultaneous bonding of two or more bonding wires to the chips, as well as performing a single bonding operation within a smaller bonding area.

To achieve the above object, the present invention provides an ultrasonic wire bonding wedge with multiple bonding wire slots. The wire bonding wedge includes a pillar fixing part for providing fixed connection to the bonding device. One end of the fixing part includes a wire bonding wedge nozzle, with feature that the tip of the nozzle including at least two bonding wire slots.

To ensure the fit of the bonding wire slot and the bonding wire, a preferred design includes that the at least two bonding wire slots are located in the middle area of the wire bonding wedge nozzle.

To ensure a smaller bonding area required by the wire bonding wedge nozzle, a preferred design includes that the wire bonding wedge nozzle has a conic structure.

To facilitate matching between the bonding wire slot and the bonding wire and avoid causing damage to the surface of the bonding wire and to propagate ultrasonic oscillation more efficiently, a preferred design includes that the width of the opening of the bonding wire slot is no less than width of any part of the bonding wire slot.

To apply to bonding wires of various shape and diameters and ensure full contact between the bonding wires and the chips, a preferred design includes that the bonding wire slot is at least one of a rectangular slot, V-shaped slot, trapezoidal slot, parabola slot and arc-shaped slot.

To ensure sufficient bonding strength of the bonding, a preferred design includes that the depth of the bonding wire slot is greater than 30 um.

The advantages and the effects of the present invention include the following:

1. The tip of nozzle of the wire bonding wedge includes at least two bonding wire slots, and is able to realize bonding operations between two or more bonding wires and the chips to improve bonding operation efficiency; and

2. When bonding operation is performed on a smaller bonding area, or two or more parallel bonding wires, the wire bonding wedge is able to perform a single bonding operation within a smaller bonding area so as to reduce defective rate of the chips and ensure sufficient bonding strength of the bonding operation.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

The present invention can be understood in more detail by reading the subsequent detailed description in conjunction with the examples and references made to the accompanying drawings, wherein:

FIG. 1 shows a schematic view of a conventional semiconductor wire bonding wedge in application;

FIG. 2 shows a schematic view of the first embodiment of the ultrasonic wire bonding wedge of the present invention;

FIG. 3 shows a partial view of the wire bonding wedge nozzle of the first embodiment of the ultrasonic wire bonding wedge of the present invention;

FIG. 4 shows a left side view of the first embodiment of the ultrasonic wire bonding wedge of the present invention;

FIG. 5 shows a top view of the structure illustrated in FIG. 4;

FIG. 6 shows a schematic view of the second embodiment of the ultrasonic wire bonding wedge of the present invention;

FIG. 7 shows a schematic view of the third embodiment of the ultrasonic wire bonding wedge of the present invention;

FIG. 8 shows a schematic view of the fourth embodiment of the ultrasonic wire bonding wedge of the present invention;

FIG. 9 shows a schematic view of the fifth embodiment of the ultrasonic wire bonding wedge of the present invention; and

FIG. 10 shows a schematic view of the sixth embodiment of the ultrasonic wire bonding wedge of the present invention.

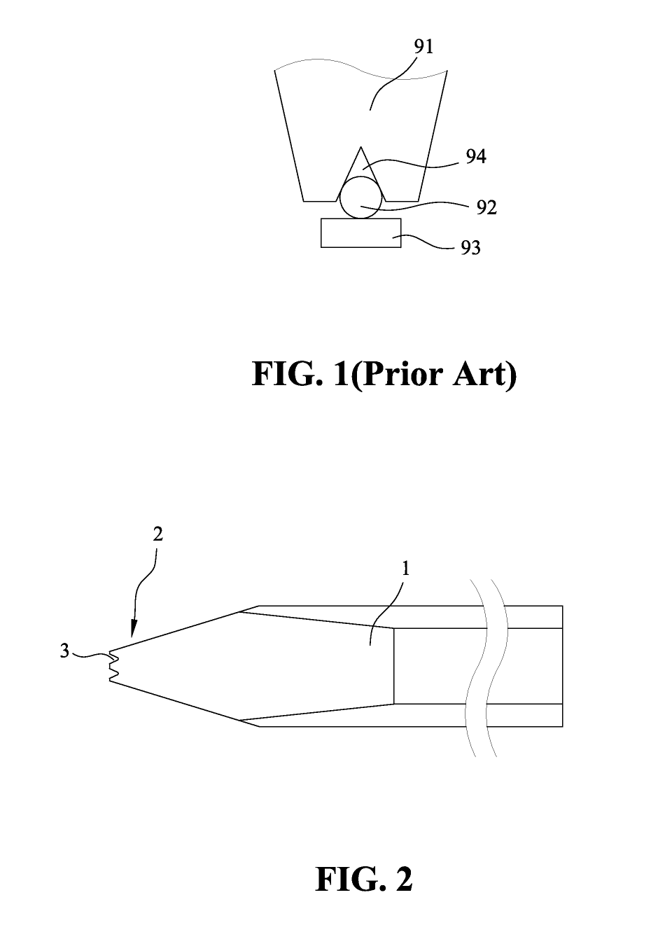

### DETAILED DESCRIPTION OF THE PREFERRED EMBODIMENTS

The following detailed description refers to embodiments, which serves as illustrative purpose for describing the technique features of the invention, instead of restriction to the scope of the present invention.

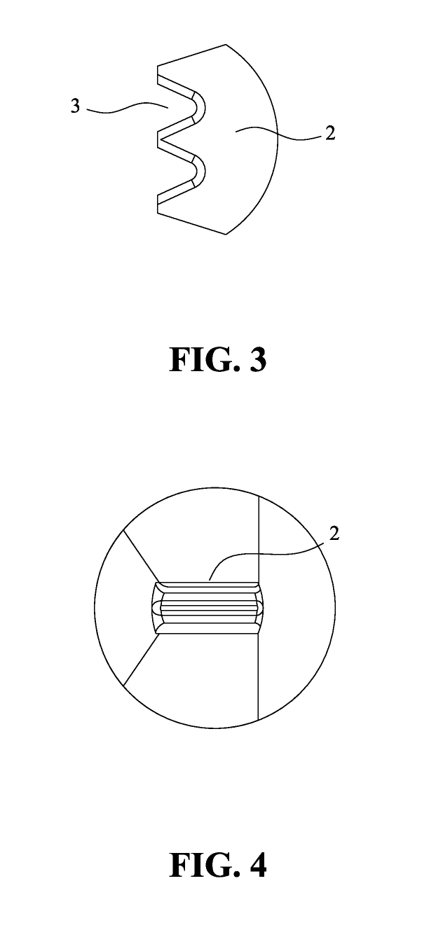

FIG. 2, FIG. 3 and FIG. 4 show the first embodiment of the present invention. An ultrasonic wire bonding wedge with multiple bonding wire slots includes a pillar fixing part 1 for providing fixed connection to the bonding device. One end of the fixing part includes a wire bonding wedge nozzle 2, with feature that the tip of the nozzle including at least two bonding wire slots 3.

In the present embodiment, the at least two bonding wire slots are located in the middle area of the wire bonding wedge nozzle. The wire bonding wedge nozzle has a conic structure. The width of the opening of the bonding wire slot is no less than width of any part of the bonding wire slot. In other words, the outermost opening has a largest width of the bonding wire slot 3. The two bonding wire slots 3 are V-shape slots of same depth. The depth of the bonding wire slot is greater than 30 um. The bonding wire slot is at least one of a rectangular slot, V-shaped slot, trapezoidal slot, parabola slot and arc-shaped slot, or any combination of at least two shapes of the above.

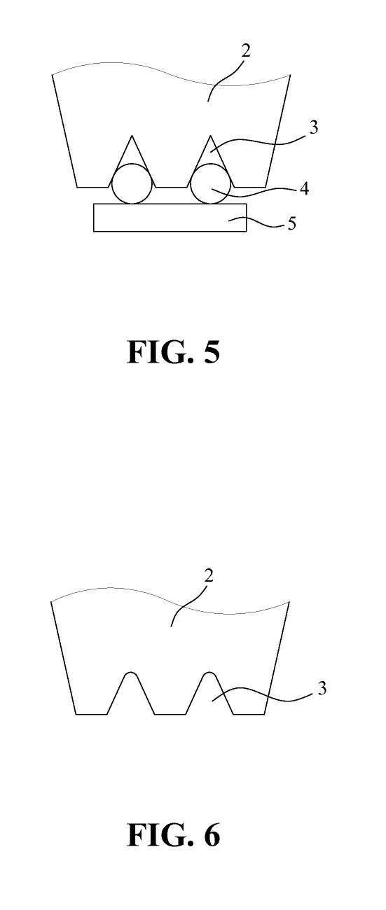

FIG. 5 shows a schematic view of the present invention in actual application. The wire bonding wedge nozzle 2 includes two bonding wire slots 3 for pressing two bonding wires 4 onto the bonding area of a chip 5. The high frequency oscillation generated by the ultrasonic bonding device is propagated through the wire bonding wedge nozzle 2 to between the surface of bonding wire 4 and the bonding area of chip 5 so that the mechanic friction between the metal surfaces to be bonded fuses the contact molecular layers of two bonding wires 4 and the chip 5 to achieve bonding under pressure.

FIG. 6 shows a schematic view of the second embodiment of the ultrasonic wire bonding wedge of the present invention. The second embodiment differs from the first embodiment in that the two bonding wire slots 3 are both a hybrid slot formed by a trapezoidal slot at the top and an arc-shaped slot at the bottom.

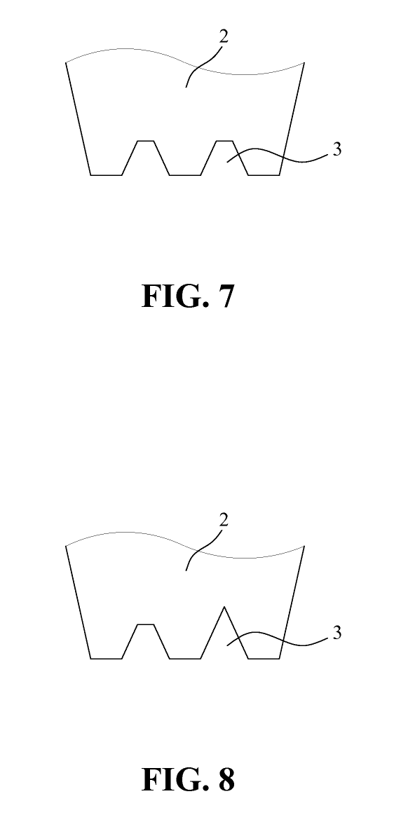

FIG. 7 shows a schematic view of the third embodiment of the ultrasonic wire bonding wedge of the present invention. The third embodiment differs from the first embodiment in that the two bonding wire slots 3 are both a trapezoidal slot of the same depth.

FIG. 8 shows a schematic view of the fourth embodiment of the ultrasonic wire bonding wedge of the present invention. The fourth embodiment differs from the first embodiment in that the two bonding wire slots 3 are of different shapes, wherein one bonding wire slot 3 is a trapezoidal slot, and the other bonding wire slot 3 is a V-shaped slot, and the two bonding wire slots 3 are of different depths.

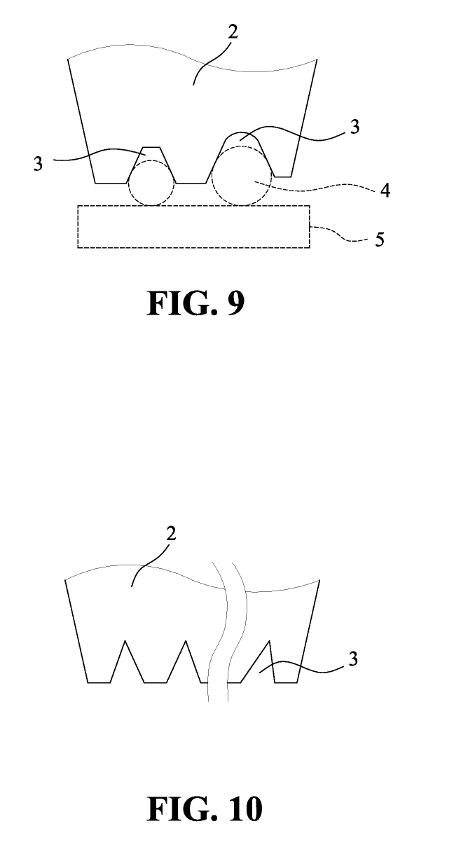

FIG. 9 shows a schematic view of the fifth embodiment of the ultrasonic wire bonding wedge of the present invention. The fifth embodiment differs from the first embodiment in that the two bonding wire slots 3 are of different shapes, wherein one bonding wire slot 3 is a trapezoidal slot, and the other bonding wire slot 3 is a hybrid slot formed by an arc-shaped slot at the top and a trapezoidal slot at the bottom. The two bonding wire slots 3 have different opening widths. The different opening widths are suitable for bonding wires of different diameters. In addition, when the bonding wire slots 3 have different opening widths, the locations of the two bonding wire slots 3 will not be on the same straight wire, as shown in the dash wire of FIG. 9, so that the bonding wires 4 of different diameters can simultaneously contact the same chip 5 in bonding operation to facilitate ultrasonic bonding operation.

FIG. 10 shows a schematic view of the sixth embodiment of the ultrasonic wire bonding wedge of the present invention. The sixth embodiment differs from the first embodiment in that at least three bonding wire slots 3 are disposed at the tip of the wire bonding wedge nozzle 2, the three bonding wire slots 3 are of different shapes.

In addition, the distance between the bonding wire slots 3 can be adjusted according to the requirement of the chips to be bonded.

Although the present invention has been described with reference to the preferred embodiments, it will be understood that the invention is not limited to the details described thereof. Various substitutions and modifications have been suggested in the foregoing description, and others will occur to those of ordinary skill in the art.

Therefore, all such substitutions and modifications are intended to be embraced within the scope of the invention as defined in the appended claims.

What is claimed is:

1. An ultrasonic wire bonding wedge with multiple bonding wire slots, comprising a pillar fixing part for providing fixed connection to the bonding device, one end of the fixing part having a wire bonding wedge nozzle, with feature that the tip of the nozzle being disposed at least two bonding wire slots.

2. The ultrasonic wire bonding wedge with multiple bonding wire slots as claimed in claim 1, wherein the at least two bonding wire slots are located in middle area of the wire bonding wedge nozzle.

3. The ultrasonic wire bonding wedge with multiple bonding wire slots as claimed in claim 1, wherein the wire bonding wedge nozzle has a conic structure.

4. The ultrasonic wire bonding wedge with multiple bonding wire slots as claimed in claim 1, wherein the bonding wire slot has an opening having a width no less than width of any part of the bonding wire slot.

5. The ultrasonic wire bonding wedge with multiple bonding wire slots as claimed in claim 1, wherein the bonding wire slot is at least one of a rectangular slot, V-shaped slot, trapezoidal slot, parabola slot and arc-shaped slot.

6. The ultrasonic wire bonding wedge with multiple bonding wire slots as claimed in claim 1, wherein the bonding wire slot is any combination of at least two shapes of a rectangular slot, V-shaped slot, trapezoidal slot, parabola slot and arc-shaped slot.

7. The ultrasonic wire bonding wedge with multiple bonding wire slots as claimed in claim 1, wherein the bonding wire slot has a depth greater than 30 um.

8. The ultrasonic wire bonding wedge with multiple bonding wire slots as claimed in claim 1, wherein the multiple bonding wire slots have the same shape.

9. The ultrasonic wire bonding wedge with multiple bonding wire slots as claimed in claim 1, wherein at least two of the multiple bonding wire slots are of different shapes.

10. The ultrasonic wire bonding wedge with multiple bonding wire slots as claimed in claim 1, wherein the multiple bonding wire slots of different shapes have the same depth.

11. The ultrasonic wire bonding wedge with multiple bonding wire slots as claimed in claim 1, wherein the multiple bonding wire slots of different shapes have different depths.

12. The ultrasonic wire bonding wedge with multiple bonding wire slots as claimed in claim 1, wherein at least two of the multiple bonding wire slots have different opening widths.

13. The ultrasonic wire bonding wedge with multiple bonding wire slots as claimed in claim 12, wherein at least two of the multiple bonding wire slots have openings not on the same straight wire.
